(19) United States
(12) Patent Application Publication
(10) Pub. No.: US 2012/0187810 A1
(43) Pub. Date: Jul. 26, 2012

(54) SUPPORTING MEMBER AND ELECTRONIC APPARATUS

(75) Inventors: Akira IWAMOTO, Osaka (JP); Masaru FURUJIKU, Osaka (JP); Yoshinari MATSUYAMA, Osaka (JP)

(73) Assignee: PANASONIC CORPORATION, Osaka (JP)

(21) Appl. No.: 13/358,054

(22) Filed: Jan. 25, 2012

(30) Foreign Application Priority Data
Jan. 25, 2011 (JP) 2011-013065
Mar. 11, 2011 (JP) 2011-054246

(51) Int. Cl. H05K 5/02; A47B 91/00

(52) U.S. Cl. 312/223.2; 312/351.1

(57) ABSTRACT

The orientation of an electronic apparatus can be stabilized. At least one foot section among the foot sections provided on a laptop computer is provided with an orientation adjustment mechanism made up of a supporting member, a height adjustment member, and a screw, which makes it possible to eliminate loose play in the first enclosure by adjusting the height of the foot sections to any given height even if loose play occurs in the first enclosure due to disproportions in the height dimensions of the foot sections, deformation etc. of the first enclosure 1, and the like.

### BACKGROUND OF THE INVENTION

1. Field of the Invention

The disclosure of the present Application relates to a supporting member supporting an apparatus on a placement surface, as well as to an electronic apparatus equipped with the supporting member.

2. Description of Related Art

An electronic apparatus that can be placed and used on a tabletop, such as a laptop computer or a desktop computer, is often equipped with supporting members, called “rubber feet”, etc. provided on a surface that is brought into resting contact with the tabletop surface serving as a placement surface. The rubber feet, which are often formed from soft rubber, provide cushioning against impacts and vibrations that may be applied to the electronic apparatus. In order to provide efficient cushioning and vibration absorption, the electronic apparatus is often equipped with multiple rubber feet.

However, in recent years, there has been a tendency to make the main body of mobile devices such as laptop computers etc. lighter in order to improve their portability, and their enclosures have been made thinner as a result. When the enclosure of an apparatus is made thinner, the application of strong impacts or pressure from the outside may result in plastic deformation, and when the enclosure undergoes plastic deformation, disproportions may occur in the resting contact state of the multiple rubber feet, i.e. some of the rubber feet may be moved out of resting contact, etc. When an electronic apparatus is placed on a tabletop, etc., its orientation becomes unstable if disproportions occur in the resting contact state of the rubber feet. Accordingly, there have been proposed configurations that allow for the height of the rubber feet to be adjusted.

In Patent Document 1 (JP H08-058189A), there is disclosed a lateral oscillation-preventing printer stand, in which, along with providing a base stand placed on a support platform, a movable frame having a printer placed thereon is disposed on the base stand and the base stand is connected to the movable frame through multiple laminate structures produced by laminating elastomeric members and rigid plate members in an alternating manner.

In addition, Patent Document 2 (JP H05-007084A) describes the structure of an installation looseness-absorbing foot section that rotatably fits into a bottom surface of a tabletop apparatus, in which there is located an adjustable foot equipped with 2-4 protruding sections provided at equi-angular intervals in radial directions on a surface opposed to the bottom surface, and, in the center, an insertion aperture, into which the adjustable foot is inserted. In this installation looseness-absorbing foot section structure, concave sections, with which the tips of the protruding sections are engaged, are provided at equi-angular intervals of theta/N in radial directions and the locations of engagement are repeated at predetermined distances in the axial direction in a stepped configuration of N steps all over the entire surface, with the height of the foot section made adjustable using an insertion seat provided in the bottom surface.

However, in the configurations disclosed in the above-described two Patent Documents, deformation of the enclosure of the tabletop apparatus as a result of external pressure and the like causes disproportions to occur in the resting contact state of the multiple adjustable feet and the orientation of the tabletop apparatus becomes unstable. In addition, in the adjustable foot disclosed in Patent Document 2, the height or number of steps (N steps) that can be adjusted is fixed and it is difficult to get rid of disproportions in the resting contact state of the multiple adjustable feet.

### SUMMARY OF THE INVENTION

The supporting member disclosed herein is a supporting member that is disposed in a foot installation section formed in an exterior surface of an apparatus enclosure and that supports an apparatus on a placement surface, wherein the supporting member: has a resting contact surface abutting the placement surface and an apparatus supporting surface abutting the foot installation section; includes a resting contact member whose one end face constitutes the resting contact surface, and a resilient member disposed closer to the apparatus supporting surface than to the resting contact surface of the resting contact member; and can be deformed such that at least one of the gap between the resting contact surface and the apparatus supporting surface and the angle between the resting contact surface and the apparatus supporting surface changes when the apparatus is placed on the placement surface.

In addition, in the electronic apparatus disclosed herein, multiple foot installation sections are formed on the exterior surface of the apparatus enclosure that faces the placement surface, and at least one foot section among the multiple foot sections disposed in the respective foot installation sections is the above-described supporting member disclosed in the present Application.

The disclosure of the present Application makes it possible to minimize disproportions in the resting contact state of the multiple foot sections and stabilize the orientation of the electronic apparatus.

### BRIEF DESCRIPTION OF THE DRAWINGS

FIG. 1 is an oblique view of a laptop computer.

FIG. 2 is a plan view of the underside of the first enclosure.

FIG. 3 is an exploded oblique view of a foot section equipped with a first orientation adjustment mechanism.

FIG. 4A is a plan view of a resting contact member.

FIG. 4B is a plan view of a resting contact member.

FIG. 4C is cross-sectional view of the X-X portion of FIG. 4B.

FIG. 5 is a cross-sectional view of the vicinity of the foot section.

FIG. 6 is a cross-sectional view of the vicinity of the foot section illustrating a state, in which the orientation of the resting contact member has been changed.

FIG. 7A is a plan view of a foot section equipped with a second orientation adjustment mechanism.

FIG. 7B is a cross-sectional view of the Z-Z portion of FIG. 7A.

FIG. 8 is a side view of a laptop computer.

FIG. 9 is a side view of the laptop computer after changing its orientation.

FIG. 10 is a cross-sectional view of the vicinity of the foot section obtained when the laptop computer is in the state illustrated in FIG. 9.

FIG. 11A is a plan view illustrating the configuration of Variation 1 of the foot section.

FIG. 11B is a cross-sectional view of the Z-Z portion of FIG. 11A.

FIG. 12A is a plan view illustrating the configuration of Variation 2 of the foot section.

FIG. 12B is a cross-sectional view of the Z-Z portion of FIG. 12A.

FIG. 13A is a plan view illustrating the configuration of Variation 3 of the foot section.

FIG. 13B is a cross-sectional view of the Z-Z portion of FIG. 13A.

FIG. 14A is a plan view illustrating the configuration of Variation 4 of the foot section.

FIG. 14B is a cross-sectional view of the Z-Z portion of FIG. 14A.

### DETAILED DESCRIPTION OF THE INVENTION

### Embodiment 1

### 1. Configuration of the Electronic Apparatus

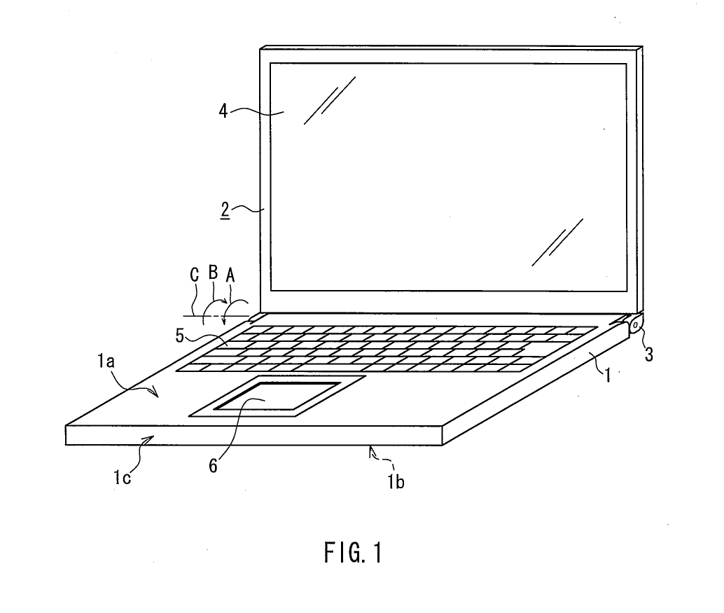

FIG. 1 is an oblique view illustrating the external appearance of a laptop computer used in this embodiment. Although a laptop computer is used as an exemplary electronic apparatus in the present embodiment, this may be any apparatus that can be used at least on a placement surface such as a tabletop.

In addition to a laptop computer, the electronic apparatus may be a desktop computer, a display device, a BD (Blu-Ray disc), a video recording and playback apparatus utilizing disc-shaped media, such as a DVD recorder/player, a desktop audio system, and the like.

As shown in FIG. 1, the laptop computer includes a first enclosure 1 and a second enclosure 2. The first enclosure 1 houses a hard disk drive, a circuit board populated with various electrical elements, and the like. The second enclosure 2 includes a display panel 4. For example, the display panel 4 can be implemented as a liquid crystal display panel. The first enclosure 1 and second enclosure 2 are supported by hinge portions 3 so as to permit rotation with respect to each other. The hinge portions 3 are equipped with a rotary shaft C, which supports the first enclosure 1 and second enclosure 2 so as to permit rotation in the directions indicated by the arrows A or B. A keyboard 5 and a pointing device 6 are located on the top surface 1a of the first enclosure 1.

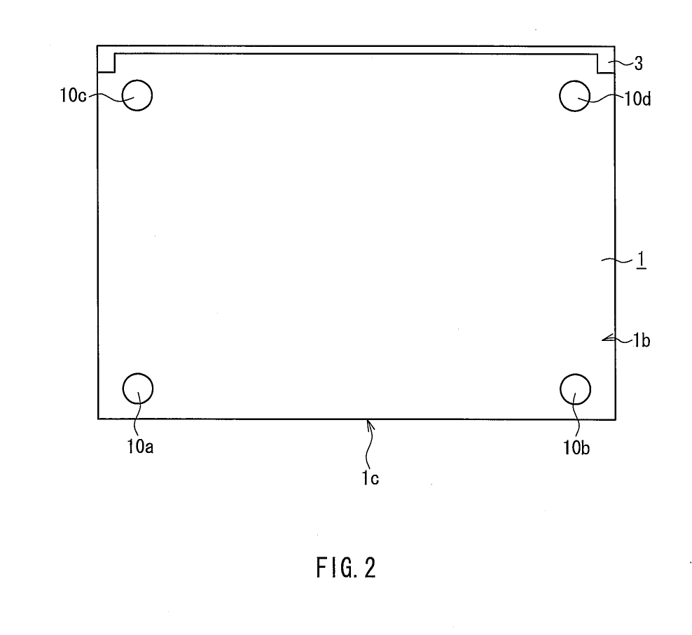

FIG. 2 is a plan view of the lower surface 1b of the first enclosure 1. The lower surface 1b of the first enclosure 1 is the surface on the opposite side of the upper surface 1a. As shown in FIG. 2, four foot sections 10a, 10b, 10c, and 10d are provided on the lower surface 1b of the first enclosure 1. At least one foot section among the foot sections 10a˜10d is the supporting member disclosed herein. It should be noted that in this Specification, the entire configuration of the supporting member disclosed herein, which is deformed into a shape where the resting contact surface and the apparatus supporting surface that are not parallel when the apparatus is placed on a placement surface, is referred to as an orientation adjustment mechanism. Accordingly, the laptop computer illustrated in FIG. 1 and FIG. 2 can be configured such that at least one foot section among the foot sections 10a˜10d is provided with an orientation adjustment mechanism.

In this embodiment, the foot sections 10a and 10b are provided with orientation adjustment mechanisms, but the foot sections 10c and 10d are not provided with orientation adjustment mechanisms. As described in this embodiment, the foot sections 10a and 10b are provided with orientation adjustment mechanisms, as a result of which, when the user operates the laptop computer in its normal orientation (with the user facing the front face 1c of the first enclosure 1 when the laptop computer is opened as illustrated in FIG. 1), the front face 1c of the first enclosure 1 may become slightly lower than the hinge section 3 because of the orientation adjustment mechanisms. Accordingly, the user can operate the keyboard 5 etc. while holding his or her hands and wrists positioned in a natural manner. If the foot sections 10c and 10d are provided with orientation adjustment mechanisms and no orientation adjustment mechanisms are provided in the foot sections 10a and 10b, the hinge section 3 of the first enclosure 1 may become lower because of the orientation adjustment mechanisms and the user may have to operate the keyboard 5 etc. while holding his or her hands and wrists in an unusual position.

In addition, all of the foot sections 10a˜10d can be made to protrude to the same height from the lower surface lb of the first enclosure 1. In addition, reducing the height by which the foot sections 10a and 10b protrude from the lower surface 1b of the first enclosure 1, in comparison with that of the foot sections 10c and 10d allows for the front face 1c of the first enclosure 1 to be made slightly lower than that of the hinge section 3, thereby allowing the user to operate the keyboard 5 etc. while holding his or her hands and wrists positioned in a natural manner.

It should be noted that while in the present Specification the supporting member that stabilizes the orientation of the laptop computer is referred to as a “foot section”, other members with similar functions are included in the scope of the supporting member of the present invention even if they have a different name (rubber feet, rubber pads, insulators, etc.).

### 2. Configuration of Foot Section Provided with First Orientation Adjustment Mechanism

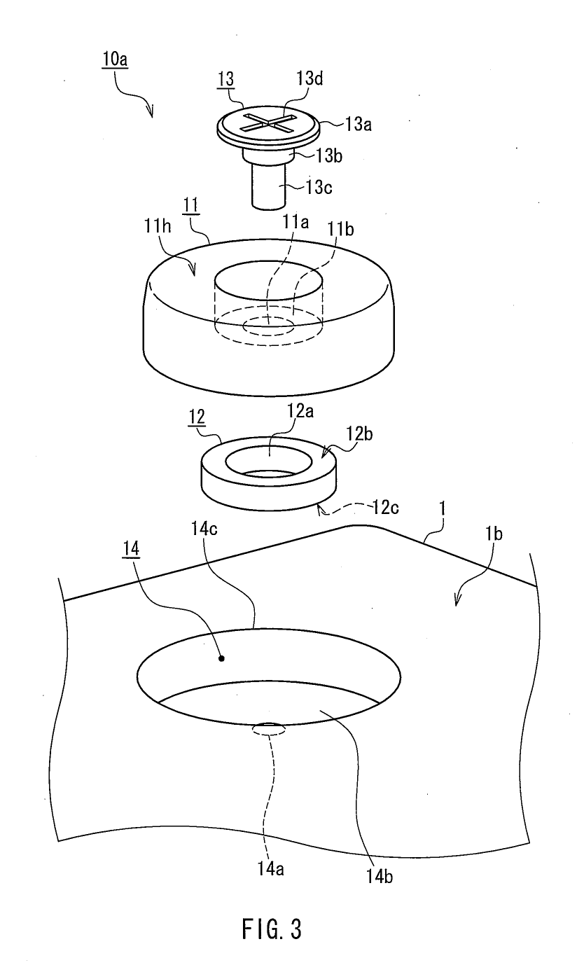

FIG. 3 is an exploded oblique view of a foot section 10a provided with a first orientation adjustment mechanism.

The first orientation adjustment mechanism has a configuration, in which a supporting member is threadedly connected to an enclosure by a screw.

It should be noted that the foot section 10b, not shown, has the same configuration as the foot section 10a.

The foot section 10a is provided with a resting contact member 11, a resilient member 12, and a screw 13. The foot section 10a is disposed on, and fixedly secured to, a foot installation section inside a recessed section 14 formed in the lower surface 1b of the first enclosure 1. When the foot section 10a is disposed in the recessed section 14, at least a portion of the resting contact member 11 protrudes from the lower surface 1b of the first enclosure 1.

When the laptop computer is placed on a tabletop in an orientation, in which the lower surface 1b faces the placement surface, the resting contact member 11 is the member brought into contact with the placement surface. The resting contact member 11 is formed into a generally cylindrical shape. The resting contact member 11 can be formed from a material that provides cushioning effects, vibration absorption effects, and positional stability, i.e. positional invariance of the laptop computer when a pressure force is applied in a direction parallel to the placement surface. More specifically, the resting contact member 11 can be formed, for instance, from a resinous material possessing so-called elastomeric properties, such as a copolymer resin possessing elasticity or visco-elasticity, an internally plasticized resin, or an resins etc. possessing rubber elasticity.

In the present embodiment, the resting contact member 11 is formed from a polyester thermoplastic elastomer (TPEE), which is used as an example of such a material. The resting contact member 11 is disposed between the resilient member 12 and the head section 13a of the screw 13. As a result of being disposed such that it protrudes from the lower surface 1b of the first enclosure 1, the resting contact member 11 can separate (raise) the first enclosure 1 from the placement surface, thereby making it difficult for vibrations and impacts to be transmitted from the placement surface to the first enclosure 1 and allowing for the impacts and vibrations transmitted from the placement surface to be absorbed by the resting contact member 11. In addition, separating the first enclosure 1 from the placement surface makes it possible to improve the heat dissipation characteristics of the first enclosure 1.

The specific configuration of the resting contact member 11 is described below.

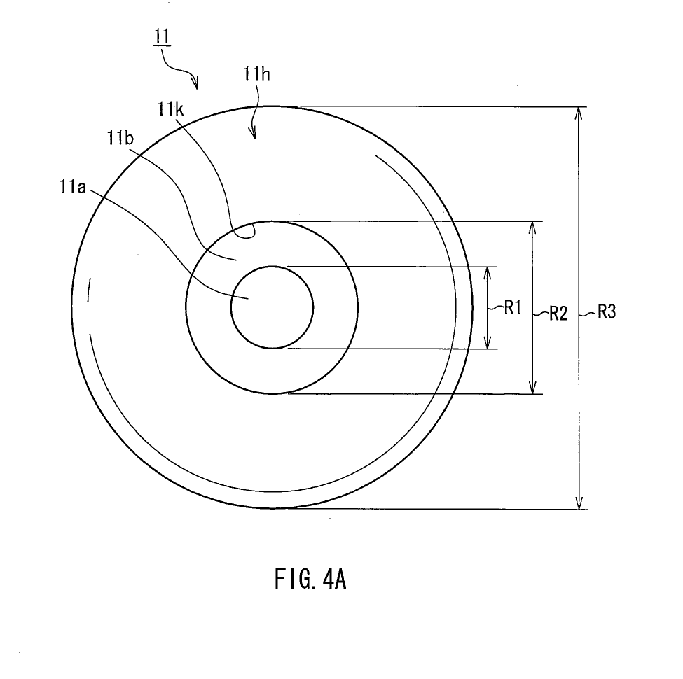

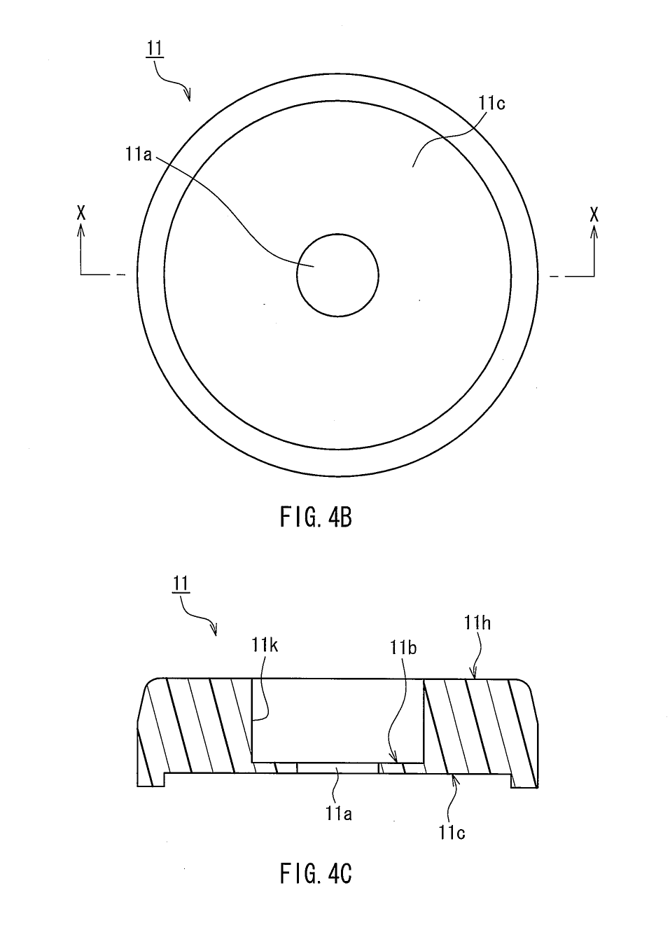

FIG. 4A is a plan view of the resting contact surface 11h of the resting contact member 11. FIG. 4B is a plan view of the reverse side of the resting contact surface 11h, i.e. the inside surface 11c of the resting contact member 11. FIG. 4C is a cross-sectional view of the X-X portion of FIG. 4B.

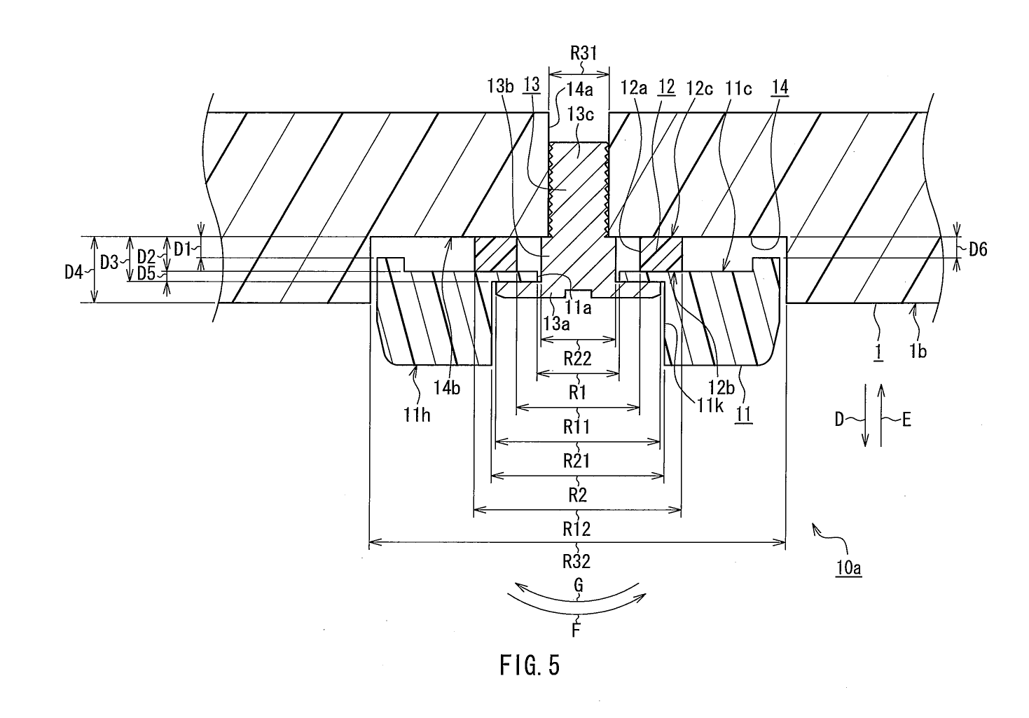

As shown in FIG. 4A-FIG. 4C, the resting contact member 11 is provided with a bore section 11a, a receiving face 11b, an inside surface 11c, a resting contact surface 11h, and a recessed section 11k. The bore section 11a is formed to the center of the receiving face 11b, i.e. the bottom surface of the recessed section 11k. The bore section 11a has an inside diameter R1 that is larger than the outside diameter of the cylindrical section 13b of the screw 13 and smaller than the outside diameter of the head section 13a of the screw 13. The receiving face 11b constitutes the portion that surrounds the bore section 11a inside the recessed section 11k. The receiving face 11b is the surface the head section 13a of the screw 13 can abut when the resting contact member 11 and the resilient member 12 are fixedly secured by the screw 13 in the recessed section 14. The inside surface 11c is the surface of the reverse side of the resting contact surface 11h. When the foot section 10a is installed on the first enclosure 1, the resting contact surface 11h is the surface that abuts the placement surface when the laptop computer is placed on a tabletop in an orientation, in which the lower surface 1b of the first enclosure 1 faces the placement surface. The recessed section 11k is formed, e.g. in the center of the resting contact surface 11h. The recessed section 11k provides a space that can accommodate at least the head section 13a of the screw 13. The depth D1 of the recessed section 11k (see FIG. 5 discussed below) is made larger than at least the thickness of the head section 13a of the screw 13, such that the head section 13a of the screw 13 does not protrude from the resting contact member 11 and the orientation of the laptop computer is stabilized when it is placed on a tabletop etc.

The resilient member 12 is a member that can allows for the orientation of the resting contact member 11 to be changed. The resting contact member 12 is formed into a generally cylindrical shape with a through hole. The resilient member 12 is disposed between the resting contact member 11 and the foot installation section, i.e. the bottom surface 14b of the recessed section 14. In the foot section equipped with the first orientation adjustment mechanism described in the present embodiment, the surface of the resilient member 12 that is on the other side of the surface that is in contact with the resting contact member 11, i.e. the surface that abuts the foot installation section, constitutes an apparatus supporting section.

To change the orientation of the resting contact member 11, the resilient member 12 is formed from a material that readily undergoes elastic deformation under external pressure and readily returns to its original shape in the absence of external pressure. As far as such members are concerned, the resilient member 12 can be formed, for instance, from polyurethane and the like. The resilient member 12 has a through hole 12a formed in a circular shape. The through hole 12a is formed through the thicknesses thereof from the first end face 12b of the resilient member 12 to its second end face 12c, i.e. to the apparatus supporting surface. To stabilize the orientation of the resting contact member 11, the first end face 12b and the second end face 12c can be formed in a planar shape and both can be formed so as to be parallel to each other.

The screw 13 can go through the bore section 11a of the resting contact member 11 and the resilient member 12 and fasten them to the foot installation section formed inside the recessed section 14 of the first enclosure 1. The screw 13 has a head section 13a, a cylindrical section 13b, and a threaded section 13c. The head section 13a has a groove 13d formed therein, into which the tip of a cross-point (+) screwdriver can be fitted. The cylindrical section 13b is formed between the head section 13a and the threaded section 13c. The threaded section 13c has a thread groove (not shown) formed on its peripheral surface in a spiral pattern. The threaded section 13c is threadedly engageable with a screw hole 14a formed inside the recessed section 14.

The recessed section 14 is formed in the lower surface lb of the first enclosure 1. Regarding the recessed section 14, the shape of the edge section 14c constituting the aperture portion is circular, but it is not limited to a circular shape and may be any other shape. The recessed section 14 has a screw hole 14a formed in the bottom surface 14b. Although in this embodiment the screw hole 14a is formed in the center of the bottom surface 14b, the location where it is formed is not limited to the center.

The FIG. 5 is a cross-sectional view illustrating a state, in which the resting contact member 11, the resilient member 12, and the screw 13 are clampingly secured to the foot installation section inside the recessed section 14.

When the foot section 10a is assembled, first of all, the resilient member 12 is disposed on the bottom surface 14b inside the recessed section 14. At such time, the resilient member 12 can be disposed at a location where the through hole 12a and the screw hole 14a are superimposed on each other, and, furthermore, can be disposed at a location where the center of the through hole 12a coincides with the center of the screw hole 14a. In addition, the resilient member 12 can restrict displacement in the planar direction of the bottom surface 14b, e.g. it can be fixedly secured to the bottom surface 14b with an adhesive agent and the like. In addition, the method used for fixedly securing the resilient member 12 is not limited to adhesive agents and may be a method in which a pawl section is formed on the bottom surface 14b and the resilient member 12 is engaged with the pawl portion; a method in which a rib fittable into the through hole 12a is formed around the screw hole 14a in the bottom surface 14b in order to position the resilient member 12; or a method, in which a groove provided with a depth sufficient to absorb at least a portion of the resilient member 12 in the thickness direction thereof is provided in the bottom surface 14b.

Next, the resting contact member 11 is disposed inside the recessed section 14. At such time, the resting contact member 11 is disposed at a location the inside surface 11c abuts the first end face 12b of the resilient member 12 and the bore section 11a overlaps with the through hole 12a of the resilient member and the screw hole 14a. The resting contact member 11 is disposed on the first end face 12b of the resilient member 12 and the second end face 12c is disposed on the bottom surface 14b, as a result of which a gap D1 is formed between it and the bottom surface 14b. In other words, the resting contact member 11 becomes separated from the bottom surface 14b by the resilient member 12.

Next, the screw 13 is passed through the bore section 11a and the through hole 12a and is threadedly engaged with the screw hole 14a. At such time, the screw 13 is threadedly engaged with the screw hole 14a until a position is reached, in which the end face of the cylindrical section 13b (end face adjacent the threaded section 13c) abuts the bottom surface 14b.

In the present embodiment, the height D3 of the cylindrical section 13b of the screw 13 in the direction of the arrows E or F, the height D2 (natural length) of the resilient member 12, and the thickness D5 of the peripheral portion of the bore section 11a of the resting contact member 11, have the relationship:

D3(D2+D5)

and, for this reason, a state is produced in which the resting contact member 11 and the resilient member 12 are sandwiched between the head section 13a of the screw 13 and the bottom surface 14b.

It should be noted that if the relationship is “D3<(D2+D5)”, the resilient member 12 is in a state of slight compressive deformation in the direction indicated by the arrow E. In addition, the height of the resting contact member 11 is set up such that, when this relationship is satisfied, the resting contact surface 11h protrudes from the lower surface 1b of the first enclosure 1.

It should be noted that the inside diameter R1 of the bore section 11a of the resting contact member 11, the inside diameter R2 of the recessed section 11b, the inside diameter R11 of the through hole 12a of the resilient member 12, the outside diameter R21 of the head section 13a of the screw 13, the outside diameter R22 of the cylindrical section 13b, the inside diameter R31 of the screw hole 14a, and the inside diameter R32 of the recessed section 14 have the relationships:

R31<R22 (Relationship 1)

R22<R11 (Relationship 2)

R1<R21<R2 (Relationship 3)

R12<R3<R32 (Relationship 4)

It should be noted that the outside diameter R3 of the resting contact member 11 is illustrated in FIG. 4A.

According to Relationship 1, the end face of the cylindrical section 13b (end face adjacent the threaded section 13c) abuts the bottom surface 14b of the recessed section 14, thereby setting the position of the screw 13 in the direction indicated by the arrow E. According to Relationship 2, the screw 13 passes through the through hole 12a of the resilient member 12. According to Relationship 3, the head section 13a of the screw 13, along with being disposed inside the recessed section 11k of the resting contact member 11, abuts the receiving face 11b of the resting contact member 11. According to Relationship 4, the resting contact member 11 is disposed inside the recessed section 14. In addition, according to Relationship 4, the resilient member 12 is disposed between the inside surface 11c of the resting contact member 11 and the bottom surface 14b of the recessed section 14.

In addition, the gap D1 between the bottom surface 14b and the inside surface 11c of the resting contact member 11, that is. the amount of separation between the resting contact member 11 and the enclosure, can be adjusted by adjusting the height D2 of the resilient member 12 or the height D3 of the cylindrical section 13b of the screw 13.

In addition, the direction indicated by the Arrow D and Arrow E generally coincides with a normal that is perpendicular to the lower surface 1b of the first enclosure 1. It should be noted that the resting contact member 11 can be displaced not only in a direction that perfectly matches a normal perpendicular to the lower surface 1b of the first enclosure 1, but also in a direction inclined relative to the normal. Therefore, as used herein, the term “normal” is not limited to directions that completely coincide with a normal to the lower surface 1b and includes directions slightly inclined relative to the normal as long as this permits displacement of the resting contact member 11 using the orientation correction capability.

### 3. Method for Adjusting Orientation of Foot Section 10a

The first enclosure 1 is often formed from metal or resin in a plate-like shape and an enclosure of such a shape often has low flexural rigidity in the vicinity of the center of its major plane. In particular, when the surface area of the upper surface la and lower surface lb of the first enclosure 1 is large or the shape of the upper surface 1a and lower surface lb of the first enclosure 1 is polygonal, the longer one of the edges is, the lower its flexural rigidity becomes.

Therefore, application of a strong pressure force to a major plane of the first enclosure 1 (for example, to the upper surface 1a illustrated in FIG. 1) may result in plastic deformation such that the lower surface 1b of the first enclosure 1 assumes a convex shape. In addition, depending on the direction of pressure application, the first enclosure 1 may undergo plastic deformation such that the upper surface 1a assumes a convex shape. When the first enclosure 1 is thus deformed, disproportions occur in the resting contact state of the multiple foot sections 10a˜10d provided on the lower surface 1b.

For example, any of the multiple foot sections 10a to 10d may be moved out of contact with the placement surface of the laptop computer. When any rubber foot among the multiple foot sections 10a˜10d is moved out of contact, the orientation of the laptop computer becomes unstable.

For example, when the user places his or her hand on the palm rest section (the section in the vicinity of the pointing device 6) of the first enclosure 1 in order to operate the keyboard 5 of the laptop computer, as well as when he or she removes the hand from the palm rest section, the orientation of the laptop computer may change. In addition, for example, in case of three-foot configurations in which only one foot section is disposed in the central portion of the hinge section 3 instead of the foot sections 10c and 10d, the planarity of the laptop computer can be ensured using only three feet, but when the keyboard 5 is operated as described above, the orientation of the laptop computer changes and its operability declines when keys are operated in the vicinity of the right end or in the vicinity of the left end. For this reason, foot sections can be disposed in the corner sections of the lower surface 1b, i.e. in at least four places.

When the resting contact member 11 of this embodiment is separated from the bottom surface 14b by the resilient member 12 and pressure is applied in this state in the direction indicated by the arrow E, it can be displaced in the direction indicated by the arrow E while the resilient member 12 is subjected to compressive deformation. Also, in this embodiment, the structure illustrated in FIG. 5 was used in the foot sections 10a and 10b.

FIG. 6 is a cross-sectional view illustrating a state, in which the resting contact member 11 of the foot section 10a is displaced in the direction indicated by the arrow E. For example, if the first enclosure 1 is not deformed by buckling, the gap between the lower surface lb and the placement surface 100 in the planar direction of the lower surface 1b will be uniform when the first enclosure 1 is placed on a desktop or another placement surface. However, if the first enclosure 1 is deformed by buckling such that the lower surface 1b is convex or concave, the gap between the lower surface 1b and the placement surface 100 in the planar direction of the lower surface 1b will be non-uniform when the first enclosure 1 is set on the placement surface 100. When the gap between the lower surface 1b and the placement surface 100 is non-uniform, at least one foot section among the multiple foot sections 10a˜10d no longer rests on the placement surface 100.

Because in this embodiment the resting contact member 11 can be displaced in the direction indicated by the arrows D or E, the resting contact member 11 of the foot section located in the vicinity of the portion where the gap between the lower surface lb and placement surface 100 is smaller can be displaced in the direction indicated by the arrow E as shown in FIG. 6. When the resting contact member 11 is displaced from the position illustrated in FIG. 5 in the direction indicated by the arrow E, the resilient member 12 undergoes compressive deformation as a result of being subjected to pressure in the direction indicated by the arrow E by the resting contact member 11.

In addition, since the screw 13 is threadedly engaged with the screw hole 14a and the cylindrical section 13b abuts the bottom surface 14b, it is not displaced even though the resting contact member 11 is displaced in the direction indicated by the arrow E. Therefore, when the resting contact member 11 is displaced as shown in FIG. 6 in the direction indicated by the arrow E, a gap is formed between the receiving face 11b of the resting contact member 11 and the head section 13a of the screw 13.

As a result, all the foot sections 10a˜10d are in resting contact.

In addition, since it is supported by the resilient member 12, the resting contact member 11 can be displaced in the direction indicated by the arrows F or G in FIG. 5. For example, the resting contact member 11 can be displaced in a tilted orientation, in which the gap D1 illustrated in FIG. 5 will be larger than the gap D2. Therefore, even if the first enclosure 1 is deformed into a shape in which the lower surface 1b of the first enclosure 1 and the placement surface 100 are not parallel, the resting contact member 11 can be brought into resting contact with in the placement surface 100 and the orientation of the laptop computer can be stabilized.

### 4. Effects, etc. of Embodiment Provided with First Orientation Adjustment Mechanism

According to this embodiment, providing at least one foot section 10a among the foot sections provided on the laptop computer with an orientation adjustment mechanism made up of a resting contact member 11, a resilient member 12, and a screw 13 makes it possible to eliminate loose play in the first enclosure 1 because all of the foot sections 10a˜10d can be brought into resting contact with the placement surface even if loose play occurs in the first enclosure 1 due to disproportions in the height dimensions of the foot sections, deformation etc. of the first enclosure 1, and the like. Consequently, the orientation of the laptop computer can be stabilized.

In particular, when the enclosure is given a thinner profile in order to make the laptop computer thinner and lighter, the rigidity of the enclosure decreases and it may be easily deformed. The problem is that when the enclosure is deformed, some of the foot sections among the multiple foot sections disposed on the lower surface of the enclosure may be moved out of contact when the laptop computer is placed on a placement surface such as a tabletop, thereby making the orientation of the laptop computer unstable. Accordingly, as described in this embodiment, the foregoing problem can be overcome by allowing for the resting contact member of at least one foot section to be displaced.

In addition, this embodiment uses a configuration, in which orientation adjustment mechanisms are provided in two foot sections, 10a and 10b, among the foot sections 10a˜10d illustrated in FIG. 2, with the foot sections 10c and 10d being fixedly secured to the first enclosure 1. For this reason, components of relatively heavy weight, such as battery packs, hard disk drives, etc., are housed in locations adjacent the hinge section 3 in the first enclosure 1, i.e. on the side where the foot sections 10c and 10d are located. In other words, even though a heavy load is continuously applied to the foot sections 10c and 10d by the heavy-weight components when the laptop computer is set on a placement surface, the orientation of the laptop computer remains stable because the foot sections 10c and 10d are fixedly secured to the first enclosure 1. If orientation adjustment mechanisms are provided in the foot sections 10c and 10d, then a heavy load is applied to the foot sections 10c and 10d by the heavy-weight components and the resting contact member 11 will end up being displaced, thereby making the orientation of the laptop computer unstable. Furthermore, when the laptop computer is used with the second enclosure 2 rotated through 100° in the direction indicated by the arrow B shown in FIG. 1, the weight of the display panel 4 is applied to the foot sections 10c and 10d, which makes the orientation of the laptop computer more prone to become more unstable.

In addition, in this embodiment, the resilient member 12 is formed into a cylindrical shape with a through hole, which stabilizes the load applied by the first enclosure 1 to the resting contact member 11 and can stabilize the orientation of the resting contact member 11.

In addition, while this embodiment uses a configuration, in which orientation adjustment mechanisms are provided in two foot sections, 10a and 10b, among the four foot sections 10a˜10d illustrated in FIG. 2, an orientation adjustment mechanism may be provided in one foot section among the foot sections 10a˜10d. It should be noted that if two or fewer rubber feet among the foot sections 10a˜10d are selected and mounted to the laptop computer, for the above⁻stated reasons, the foot sections 10a or 10b can be mounted.

In addition, although in this embodiment the resilient member 12 was formed from an elastic material such as polyurethane and the like, it is sufficient to use a configuration in which the resting contact member 11 at least can be separated from the bottom surface 14b, and the resilient member 12 can be implemented as a coil spring or leaf spring.

In addition, although this embodiment uses a configuration in which the resilient member 12 is fixedly secured to the bottom surface 14b of the recessed section 14, it is also possible to use a configuration in which it is fixedly secured to the inside surface 11c of the resting contact member 11.

In addition, although in this embodiment the resilient member 12 was provided separately from the resting contact member 11, depending upon the material of the resting contact member 11, a rib of the same shape as the resilient member 12 described in the present embodiment may be integrally molded on the inside surface 11c of the resting contact member 11 as a resilient member instead of the separate resilient member 12. In addition, instead of the resilient member 12, a rib of the same shape as the resilient member 12 described in the present embodiment may integrally molded on the bottom surface 14b of the recessed section 14. At such time, the rib must possess elasticity equal to that of the resilient member 12 described in the present embodiment.

In addition, although in this embodiment FIG. 6 illustrates a configuration in which the resting contact member 11 is displaced in the direction indicated by the arrow E while preserving the parallel relation between the inside surface 11c and the bottom surface 14b, the resting contact member 11 also can assume a tilted orientation, in which the inside surface 11c and the bottom surface 14b are not parallel. If such a configuration is used, then the resting contact surfaces of the resting contact members 11 of all the foot sections 10a˜10d can be brought into resting contact with the placement surface 100 even if the lower surface 1b of the first enclosure 1 is deformed into a shape that is not parallel to the placement surface 100.

In addition, although in this embodiment a recessed section 14 was provided in the first enclosure 1, the recessed section 14 may be omitted. If the recessed section 14 is omitted, the foot sections 10a˜10d are disposed on foot installation sections formed in the lower surface 1b of the first enclosure 1.

In addition, while this embodiment used a screw 13 to affix the resting contact member 11 and the resilient member 12 to the first enclosure 1, retaining members other than screws may be used as long as the resting contact member 11 and resilient member 12 can be affixed to the first enclosure 1.

The resting contact member 11 in this embodiment is an exemplary resting contact member. The resilient member 12 used in this embodiment is an exemplary resilient member. The bottom surface 14b of the recessed section 14 in this embodiment is an exemplary foot installation section. The first enclosure 1 in this embodiment is an exemplary enclosure. The lower surface 1b in this embodiment is an example of an exterior surface of the enclosure that faces the placement surface. The foot sections 10a˜10d in this embodiment are an example of multiple foot sections. The foot sections 10a or 10b in this embodiment are exemplary supporting members.

### Embodiment 2

Next, a laptop computer provided with a supporting member different from the supporting member described in Embodiment 1 above, namely, a member provided with a foot section equipped with a second orientation adjustment mechanism, will be described as Embodiment 2 below. It should be noted while the configuration of the supporting member of the laptop computer described in Embodiment 2 is different from the laptop computer described in Embodiment 1, it is similar to Embodiment 1 in terms of the configuration of the first enclosure and second enclosure. For this reason, in Embodiment 2, descriptions related to specific exemplary configurations of the first enclosure and second enclosure of the laptop computer are omitted.

### 5. Configuration of Foot Section Provided with Second Orientation Adjustment Mechanism

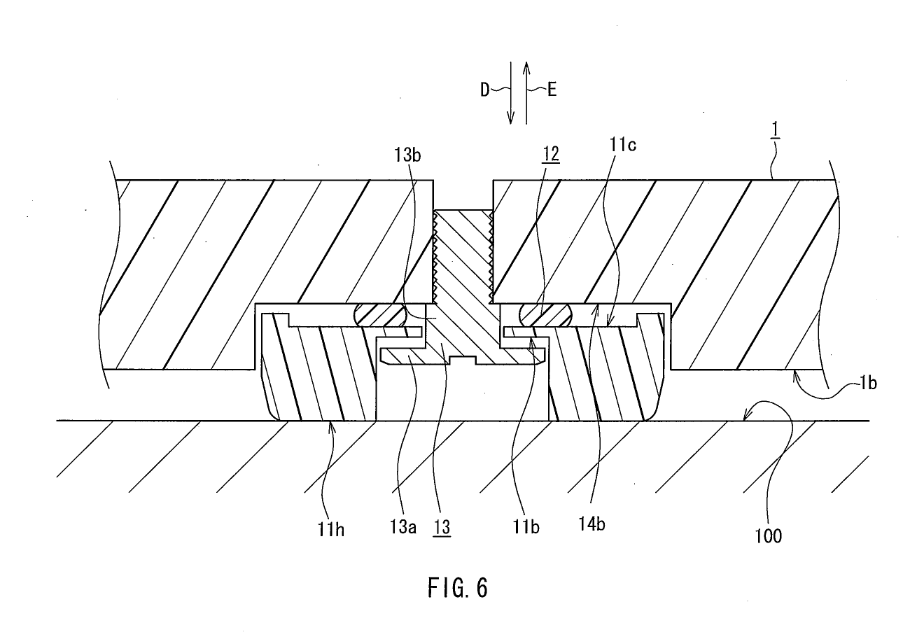

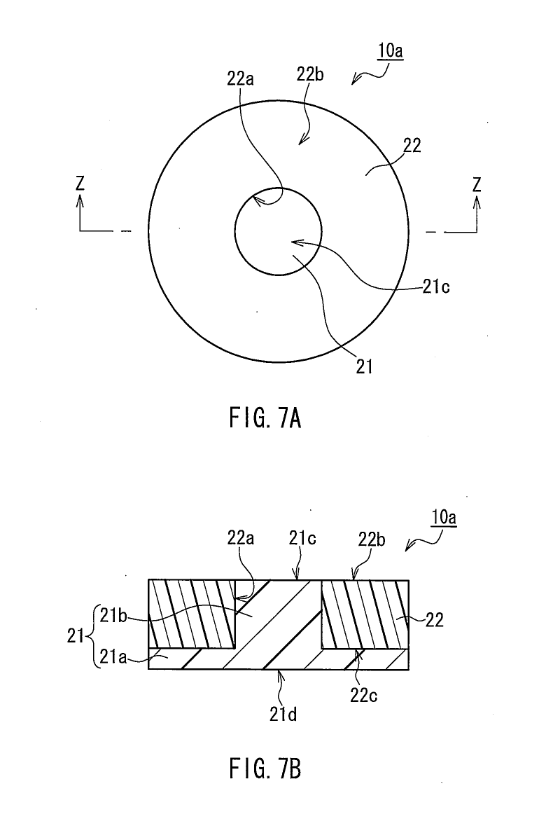

FIG. 7A is a plan view of a foot section 10a equipped with a second orientation adjustment mechanism, as viewed from its lower surface 1b.

The foot section equipped with the first orientation adjustment mechanism, which was described in Embodiment 1, employed a basic configuration, in which it was threadedly connected to the enclosure by a screw and the resting contact member was separated from the enclosure. However, the second orientation adjustment mechanism employs a basic configuration in which the resting contact member of the foot section is joined to the enclosure.

FIG. 7B is a cross-sectional view of the Z-Z portion of FIG. 7A. The foot section 10a is formed into a cylindrical shape. The foot section 10a is equipped with a first supporting section 21, which is a resting contact member, and a second supporting section 22, which is a resilient member.

The first supporting section 21 is equipped with a resting contact section 21a formed into a disk-like shape and a shank section 21b formed into a cylindrical shape. The resting contact section 21a and shank section 21b are formed integrally from the same material. The first supporting section 21 is formed from a material whose hardness is higher than that of the second supporting section 22. The first supporting section 21 is preferably formed from a material that provides cushioning effects, vibration absorption effects, and positional stability, i.e. positional invariance of the laptop computer when a pressure force is applied thereto in a direction parallel to the placement surface.

The first supporting section 21 can be formed, for example, from resinous materials possessing so-called elastomeric properties, such as copolymer resins possessing elasticity or visco-elasticity (also referred to as tackiness, etc.), internally plasticized resins, or resins and the like possessing rubber elasticity. Specifically, the first supporting section 21 can be formed, for instance, from a polyester thermoplastic elastomer (TPEE).

Due to being disposed such that it protrudes from the lower surface lb of the first enclosure 1, the first supporting section 21 can separate the first enclosure 1 from the placement surface, thereby making it difficult for vibrations and impacts to be transmitted from the placement surface to the first enclosure 1 and allowing for the impacts and vibrations transmitted from the placement surface to be absorbed by the first supporting section 21. In addition, separating the first enclosure 1 from the placement surface allows for the heat dissipation characteristics of the first enclosure 1 to be improved.

When the laptop computer is set on a placement surface, the lower surface 21d of the resting contact section 21a, which serves as a resting contact surface, is brought into contact with the placement surface. Since the outside diameter R1 of the resting contact section 21a is made larger than the outside diameter R2 of the shank section 21b, the second supporting section 22 can be disposed in the space bordered by the resting contact section 21a and the shank section 21b.

In this embodiment, the shank section 21b is formed in a location overlapping with the center of the resting contact section 21a formed in a disk-like shape. The shank section 21b is not limited to shanks whose center coincides with the center of the resting contact section 21a and is disposed such that it is located in the approximate center of the resting contact section 21a.

In this embodiment, when the foot section 10a is fixedly secured to the lower surface 1b of the first enclosure 1, the upper surface 21c of the shank section 21b, i.e. the apparatus supporting surface, is joined to the foot installation section on the lower surface 1b of the first enclosure 1 using an adhesive agent. The method used to join the shank section 21b to the lower surface 1b of the first enclosure 1 includes, but is not limited to, joining using adhesive agents, threaded connection using screws, etc. It should be noted that if the upper surface 22b of the second supporting section 22, i.e. the apparatus supporting surface, is joined to the lower surface 1b of the first enclosure 1, the upper surface 21c of the shank section 21b does not need to be joined to the lower surface 1b of the first enclosure 1. In addition, in order to reliably and fixedly secure the foot section 10a to the lower surface 1b of the first enclosure 1, the upper surface 21c of the shank section 21b can be joined to the lower surface 1b of the first enclosure 1 and, furthermore, the upper surface 22b of the second supporting section 22 can be joined to the lower surface 1b of the first enclosure 1.

The second supporting section 22 is formed into a generally cylindrical shape. To change the orientation of the first enclosure 1 and first supporting section 21, the second supporting section 22 is formed from a material that undergoes elastic deformation under external pressure more readily than the first supporting section 21 and readily returns to its original shape in the absence of external pressure.

The second supporting section 22 is formed from a material whose hardness is lower than that of the first supporting section 21. The second supporting section 22 can be formed, for instance, from polyurethane and the like. The second supporting section 22 has a bore section 22a, which is a through hole, formed in a circular shape. The bore section 22a is formed through the thickness of the second supporting section 22 from the upper surface 22b to the lower surface 22c. The shank section 21b of the first supporting section 21 is fitted into the bore section 22a. The upper surface 22b of the second supporting section 22 is joined to the lower surface 1b of the first enclosure 1. In order to be in surface-abutting contact with the lower surface 1b of the first enclosure 1, the upper surface 22b is preferably flat, and, furthermore, it is preferably located in the same plane as the joint surface 21c of the first supporting section 21. It should be noted that if the upper surface 21c of the first supporting section 21 is joined to the lower surface 1b of the first enclosure 1, the upper surface 22b does not need to be joined to the lower surface 1b of the first enclosure 1. However, in order to reliably fixedly secure the foot section 10a to the lower surface 1b of the first enclosure 1, the upper surface 22b can be joined to the lower surface 1b of the first enclosure 1. Although in this embodiment the lower surface 22c is joined to the resting contact section 21a of the first supporting section 21, as long as it can abut the resting contact section 21a, it does not need to be joined thereto.

It should be noted that while in the configuration illustrated in FIG. 7A and FIG. 7B the second supporting section 22 is disposed around the entire perimeter of the shank section 21b of the first supporting section 21, disposing it around at least a portion of the perimeter of the shank section 21b is sufficient. In addition, the second supporting section 22 can be configured to be disposed in the space bordered by the resting contact section 21a of the first supporting section 21 and the shank section 21b.

The operation of adjusting the orientation of the foot section 10a will be described below.

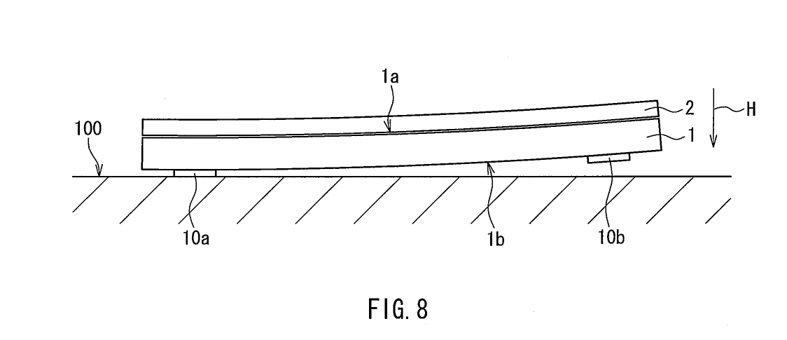

FIG. 8 is a side view illustrating a state, in which the laptop computer is set on a placement surface 100. FIG. 8 shows the laptop computer as viewed in the direction facing the front face 1c of the first enclosure 1 illustrated in FIG. 1.

The laptop computer illustrated in FIG. 8 is closed. The term “closed” refers to a state produced by rotating the second enclosure 2 in the direction indicated by the arrow A in the state illustrated in FIG. 1 such that the display panel 4 and the keyboard 5 are brought together into a face-to-face relationship. In addition, in this case, the first enclosure 1 illustrated in FIG. 8 is shown deformed by buckling such that the upper surface 1a of the first enclosure 1 becomes concave. The second enclosure 2 illustrated in FIG. 8 is also deformed by buckling in parallel with the first enclosure 1. It should be noted that while FIG. 8 shows the first enclosure 1 and second enclosure 2 in a considerably buckled state in order to illustrate clearly the resting contact state of the foot sections 10a and 10b, the actual amount of deformation of the first enclosure 1 and second enclosure 2 is often smaller.

As shown in FIG. 8, when the first enclosure 1 and second enclosure 2 are deformed by buckling, imbalances may occur in the resting contact state of the foot sections 10a˜10d provided on the lower surface 1b of the first enclosure 1 (only the foot sections 10a and 10b are shown in FIG. 8). In the example illustrated in FIG. 8, the centers of the first enclosure 1 and second enclosure 2 are deformed by buckling into a convex shape in the direction of the placement surface 100, as a result of which the foot section 10a is in resting contact with the placement surface 100 while the foot section 10b is separated from (raised above) the placement surface 100. Thus, when disproportions occur in the resting contact state of the foot sections 10a˜10d, the orientation of the laptop computer becomes unstable, which hinders entry operations via the keyboard 5.

In this embodiment, as shown in FIG. 7A and FIG. 7B, the foot section 10a is provided with a second orientation adjustment structure, namely, the first supporting section 21, which serves as a resting contact member, and the second supporting section 22, which serves a resilient member. Specifically, the foot section 10a is equipped with a second supporting section 22, which is formed from a material of a lower hardness than the first supporting section 21. The second supporting section 22 is disposed between the lower surface 1b of the first enclosure 1 and the resting contact section 21a of the first supporting section 21. By using such a configuration the first enclosure 1 can change its orientation while subjecting the second supporting section 22 to elastic deformation along the axis of the shank section 21b.

For example, when the first enclosure 1 is deformed by buckling as shown in FIG. 8, the first enclosure 1 can change its orientation in the direction indicated by the arrow H while subjecting the second supporting section 22 to elastic deformation along the axis of the shank section 21b of the foot section 10a (see FIG. 7B).

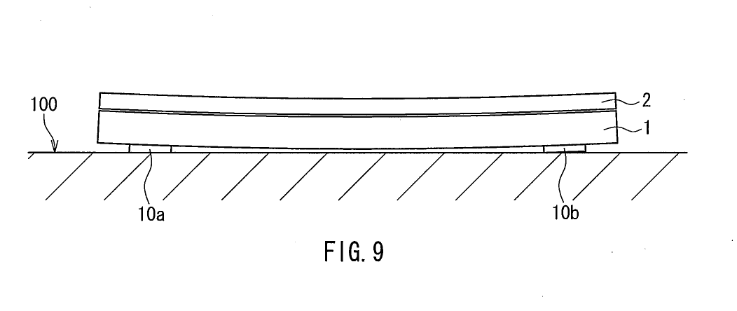

FIG. 9 illustrates a state, in which the orientation is changed in the direction indicated by the arrow H in comparison with the state of the first enclosure 1 illustrated in FIG. 8.

As shown in FIG. 9, when the first enclosure 1 changes its orientation from the orientation illustrated in FIG. 8 in the direction indicated by the arrow H and the foot section 10b is brought into resting contact with the placement surface 100, the orientation of the laptop computer is stabilized because the foot section 10a and foot section 10b are in resting contact with the placement surface 100.

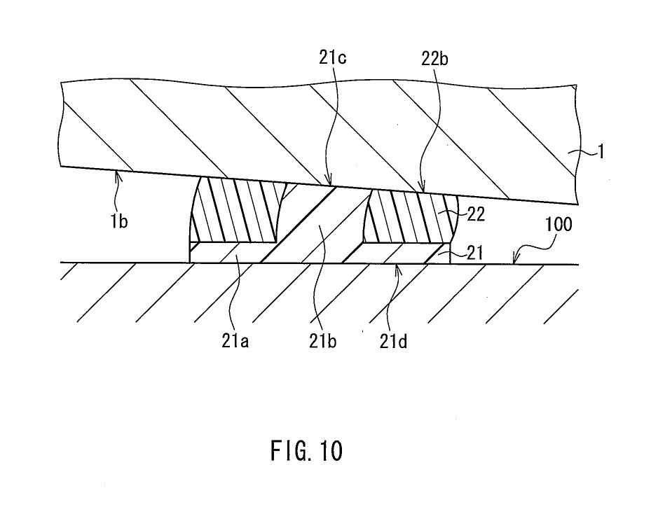

FIG. 10 is an enlarged cross sectional view of the foot section 10a in the state illustrated in FIG. 9.

As shown in FIG. 10, the foot section 10a undergoes elastic deformation following changes in the gap between the lower surface 1b of the first enclosure 1 and the placement surface 100 that take place as the first enclosure 1 transitions from the state illustrated in FIG. 8 to the state illustrated in FIG. 9. Specifically, the foot section 10a is provided with the second supporting section 22 of a lower hardness between the lower surface 1b of the first enclosure 1 and the resting contact section 21a, and, as shown in FIG. 9, when the gap between the lower surface 1b of the first enclosure 1 and the placement surface 100 changes, the second supporting section 22 undergoes elastic deformation while the relative position of the resting contact section 21a with respect to the first enclosure 1 is changed. More specifically, the foot section 10a is deformed such that the lower surface 21d of the first supporting section 21, which serves as a resting contact surface, is not parallel to the upper surface of the first supporting section 21, which serves as an apparatus supporting surface, and the upper surface of the second supporting section 22, thereby creating an angle between the two surfaces. Consequently, while the lower surface 21d of the resting contact section 21a of the foot section 10a remains in resting contact with the placement surface 100, the foot section 10b of the first enclosure 1 can be displaced in the direction indicated by the arrow H, thereby making it possible to bring the foot section 10b into resting contact.

It should be noted that when the amount of deformation of the first enclosure 1 is small, as shown in FIG. 10, the lower surface 21d of the resting contact section 21a often abuts the placement surface 100 in a planar fashion. As a result, the orientation of the laptop computer is stabilized. However, the lower surface 21d of the resting contact section 21a does not have to abut the placement surface 100 in a planar fashion and the orientation of the laptop computer can be stabilized if at least a portion of the lower surface 21d of the resting contact section 21a abuts the placement surface 100.

### 6. Effects, etc. of Embodiment Provided with Second Orientation Adjustment Mechanism

According to this embodiment, at least one foot section among the multiple foot sections provided on the laptop computer (in this embodiment, the foot sections 10a and 10b) is provided with an orientation adjustment structure made up of the first supporting section 21 and second supporting section 22, and, as a result, even if disproportions occur in the state of resting contact of the foot sections 10a˜10d with the placement surface 100 because of disproportions in the height dimensions of the foot sections and deformation etc. of the first enclosure 1, all the foot sections 10a˜10d can be brought into resting contact with the placement surface 100. Therefore, loose play in the orientation of the first enclosure 1 can be eliminated and the orientation of the laptop computer can be stabilized.

In addition, in accordance with this embodiment, the first supporting section 21 is provided with the resting contact section 21a formed from a material of high hardness, which makes it possible to improve wear resistance in the portion where it is in contact with the placement surface 100.

In addition, in accordance with this embodiment, the first supporting section 21 is provided with a resting contact section 21a and a shank section 21b, both of which are formed from materials of high hardness, thereby making reduction in the stress resistance of the foot section less pronounced and making it possible to withstand external disturbances applied in directions parallel to the plane of the placement surface 100 as well as masses applied in directions perpendicular to the placement surface 100.

In particular, when the enclosure is given a thinner profile in order to make the laptop computer thinner and lighter, the rigidity of the enclosure decreases and it may be deformed easily. The problem is that when the enclosure is deformed, some of the foot sections among the multiple foot sections disposed on the lower surface of the enclosure may be moved out of contact when the laptop computer is placed on a placement surface such as a tabletop, thereby making the orientation of the laptop computer unstable. Accordingly, as described in this embodiment, the foregoing problem can be overcome by providing at least one foot section with an orientation adjustment structure.

In addition, in this embodiment, the second supporting section 22 is formed into a cylindrical shape, which stabilizes the load applied by the first enclosure 1 to the first supporting section 21 and can stabilize the orientation of the first supporting section 21.

In addition, while this embodiment uses a configuration in which orientation adjustment structures are provided in foot sections 10a and 10b among the four foot sections 10a˜10d illustrated in FIG. 2, an orientation adjustment structure may be provided in one foot section among the foot sections 10a˜10d.

An orientation adjustment structure can be provided in at least one section among the foot sections 10a and 10b. For this reason, components of relatively heavy weight, such as battery packs, hard disk drives, etc., are housed in locations adjacent the hinge section 3 in the first enclosure 1, i.e. on the side where the foot sections 10c and 10d are located. In other words, since a heavy load is applied continuously to the foot sections 10c and 10d by the heavy-weight components when the laptop computer is set on a placement surface, the orientation of the laptop computer remains more stable when the foot sections 10c and 10d have no orientation adjustment structures. If orientation adjustment structures are provided in the foot sections 10c and 10d, then a heavy load is applied to the foot sections 10c and 10d by the heavy-weight components and the orientation of the laptop computer becomes unstable. Furthermore, when the laptop computer is used with the second enclosure 2 rotated through 100° in the direction indicated by the arrow B shown in FIG. 1, the weight of the display panel 4 is applied to the foot sections 10c and 10d, which makes the orientation of the laptop computer more prone to become more unstable. For these reasons, an orientation adjustment structure can be provided in at least one section among the foot sections 10a and 10b.

In addition, the overall shape of the foot sections 10a˜10d was illustrated using a cylindrical shape, but other shapes, such as prismatic shapes, may also be used.

In addition, the apparatus supporting surface (for example, the upper surface 21c or 22b), which is joined to the first enclosure 1 in the foot sections 10a˜10d, does not have to be a planar surface and may be shaped to match the shape of the lower surface 1b of the first enclosure 1.

In addition, the lower surface 21d of the resting contact section 21a, which serves as a resting contact surface, does not have to be a planar surface and may have a different shape. For example, making the lower surface 21d of the resting contact section 21a spherical, etc. can improve its ability to conform to the placement surface 100 when the first enclosure 1 is deformed and can further stabilize the orientation of the laptop computer.

Furthermore, the following variations are disclosed in this embodiment.

### Variation 1

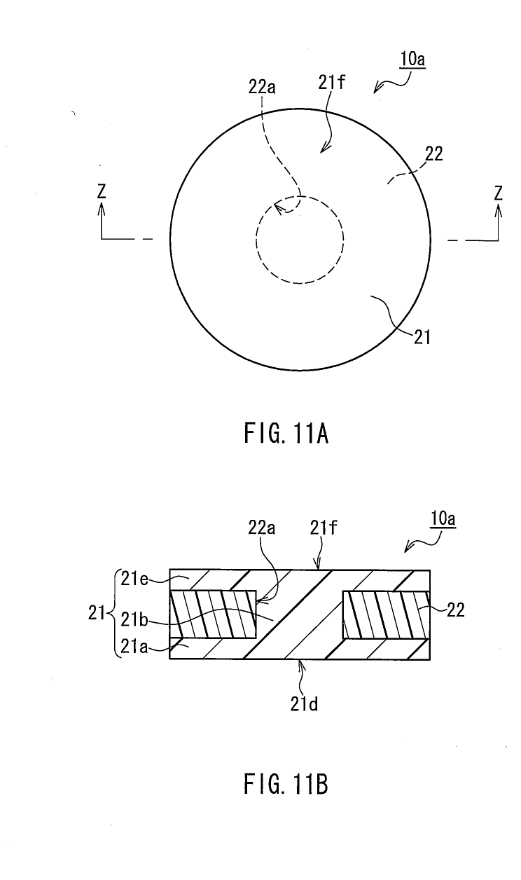

FIG. 11A is a plan view illustrating the configuration of Variation 1 of the foot section. FIG. 11B is a cross-sectional view of the Z-Z portion of FIG. 11A. In the foot section 10a illustrated in FIG. 11A and FIG. 11B, parts identical to those of the foot section 10a illustrated in FIG. 7A and the FIG. 7B are assigned identical reference numerals and their detailed descriptions are omitted.

In addition to the first supporting section 21 illustrated in FIG. 7A and FIG. 7B, the foot section 10a illustrated in FIG. 11A and FIG. 11B is further provided with an apparatus supporting section 21e. The apparatus supporting section 21e is formed into a disk-like shape. The apparatus supporting section 21e is formed integrally with the shank section 21b from the same material as the resting contact section 21a and shank section 21b. The apparatus supporting section 21e faces the resting contact section 21a, with the second supporting section 22 sandwiched therebetween. The apparatus supporting section 21e has an upper surface 21f, which serves as an apparatus supporting surface and is formed in a planar shape. The upper surface 21f of the apparatus supporting section 21e is joined to a foot installation section in the lower surface 1b of the first enclosure 1. The outside diameter R3 of the apparatus supporting section 21e is larger than the shank diameter R2 of the shank section 21b and is of the same size as the outside diameter R1 of the resting contact section 21a. It should be noted that while the outside diameter R1 of the resting contact section 21a and the outside diameter R3 of the apparatus supporting section 21e may be of different sizes, the outside diameter R1 of the resting contact section 21a and the outside diameter R3 of the apparatus supporting section 21e are preferably configured to satisfy the relationship of R3≧R1. In addition, when the relationship R3>R1 is satisfied, the external shape of the second supporting member 22 may be a frustum shape that connects R3 to R1.

In the same manner as the foot section 10a illustrated in FIG. 7A and FIG. 7B, the foot section 10a illustrated in FIG. 11A and FIG. 11B operates to adjust the orientation of the first enclosure 1 by elastically deforming the second supporting section 22 while supporting the first enclosure 1 on the first supporting section 21, and a further detailed description is omitted herein.

Adopting such a configuration can ensure adhesion to the lower surface lb of the first enclosure 1. Namely, since the apparatus supporting section 21e is provided with the upper surface 21f formed as a planar surface, when the foot section 10a is joined to the lower surface 1b of the first enclosure 1, it can abut reliably it in a planar fashion, and, therefore, the upper surface 21f can be bonded reliably to the lower surface 1b of the first enclosure 1.

It should be noted that the resting contact section 21a and apparatus supporting section 21e have the same geometry and the second supporting section 22 can be formed in the central portion in the direction of thickness between the upper surface 21f and lower surface 21d of the first supporting section 21. Using such a configuration makes it possible to improve assembly characteristics without identifying the orientation of the foot section 10a when the foot section 10a is joined to the lower surface 1b of the first enclosure 1. Namely, since the functionality does not change if the upper surface 21f or lower surface 21d of the foot section 10a is joined to the lower surface 1b of the first enclosure 1, the foot section 10a can be joined to the lower surface 1b of the first enclosure 1 without identifying the orientation of the foot section 10a.

### Variation 2

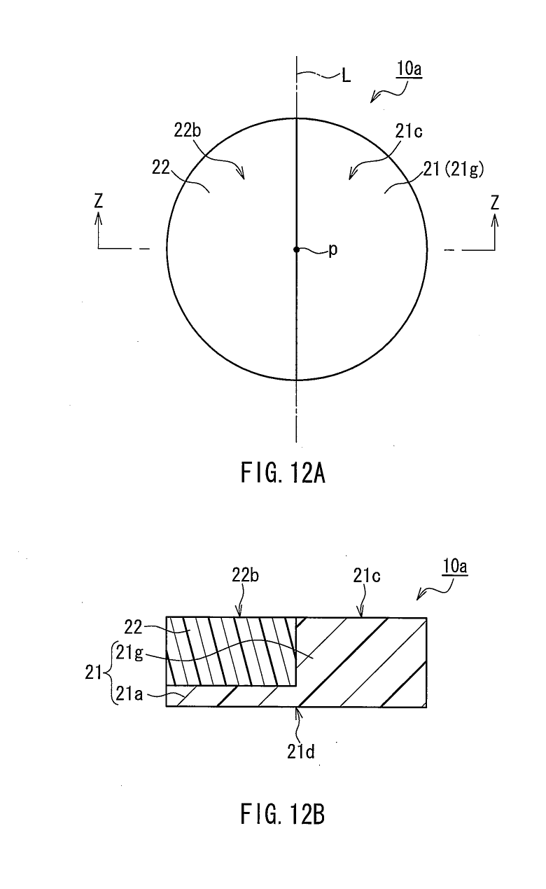

FIG. 12A is a plan view illustrating the configuration of Variation 2 of the foot section. FIG. 12B is a cross-sectional view of the Z-Z portion of FIG. 12A. In the foot section 10a illustrated in FIG. 12A and FIG. 12B, parts identical to those of the foot section 10a illustrated in FIG. 7A and the FIG. 7B are assigned identical reference numerals and their detailed descriptions are omitted.

The configuration of the foot section 10a illustrated in FIG. 12A and FIG. 12B is obtained by changing the shape of the first supporting section 21 and second supporting section 22 illustrated in FIG. 7A and FIG. 7B. The first supporting section 21 is equipped with a resting contact section 21a and a shank section 21g. The shank section 21g is formed into a half-cylinder shape. The shank section 21g is formed integrally with the resting contact section 21a from the same material as the resting contact section 21a. The upper surface 21c of the shank section 21g, which serves as an apparatus supporting surface, is joined to a foot installation section in the lower surface 1b of the first enclosure 1. The second supporting section 22 is formed into a half-cylinder shape. The material of the second supporting section 22 is the same as that of the second supporting section 22 illustrated in FIG. 7A and FIG. 7B. The upper surface 22b of the second supporting section 22, which serves as an apparatus supporting surface, is located in the same plane as the upper surface 21c of the shank section 21g. As shown in FIG. 12A, the boundary surface between the first supporting section 21 and second supporting section 22 is located such that it passes through the center P of the foot section 10a.

The foot section 10a illustrated in FIG. 12A and FIG. 12B can adjust the orientation of the first enclosure 1 by elastically deforming the second supporting section 22 while supporting the first enclosure 1 on the first supporting section 21.

The foot section 10a illustrated in FIG. 12A and FIG. 12B is provided with a second supporting section 22 on one side only, with the line segment L passing through the center P of the foot section 10a used as a boundary.

### Variation 3

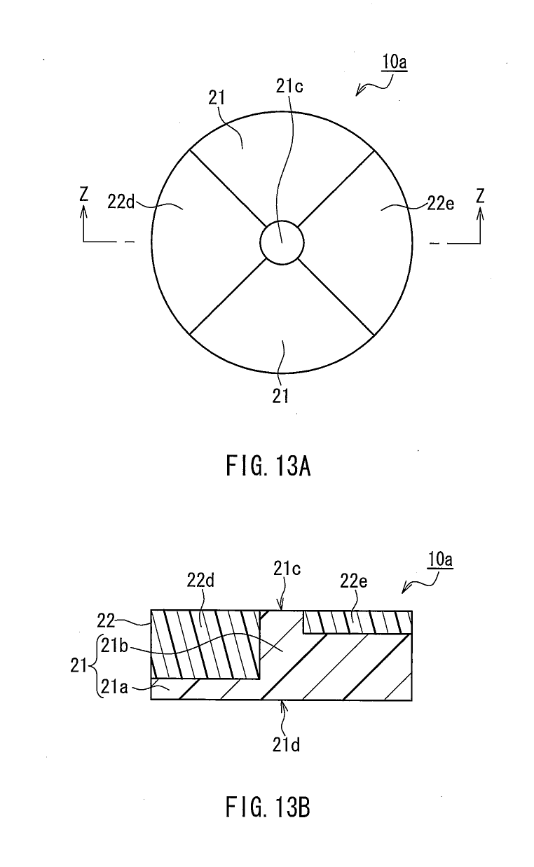

FIG. 13A is a plan view illustrating the configuration of Variation 3 of the foot section. FIG. 13B is a cross-sectional view of the Z-Z portion of FIG. 13A. In the foot section 10a illustrated in FIG. 13A and FIG. 13B, parts identical to those of the foot section 10a illustrated in FIG. 7A and the FIG. 7B are assigned identical reference numerals and their detailed descriptions are omitted.

The second supporting section 22 illustrated in FIG. 13A is configured such that the second supporting section 22 of the foot section 10a illustrated in FIG. 7A and FIG. 7B is provided only in a portion of the first supporting section 21 in its circumferential direction. In addition, as shown in FIG. 13B, the second supporting section 22 is made up of a third supporting section 22d and a fourth supporting section 22e, which are of different thickness.

### Variation 4

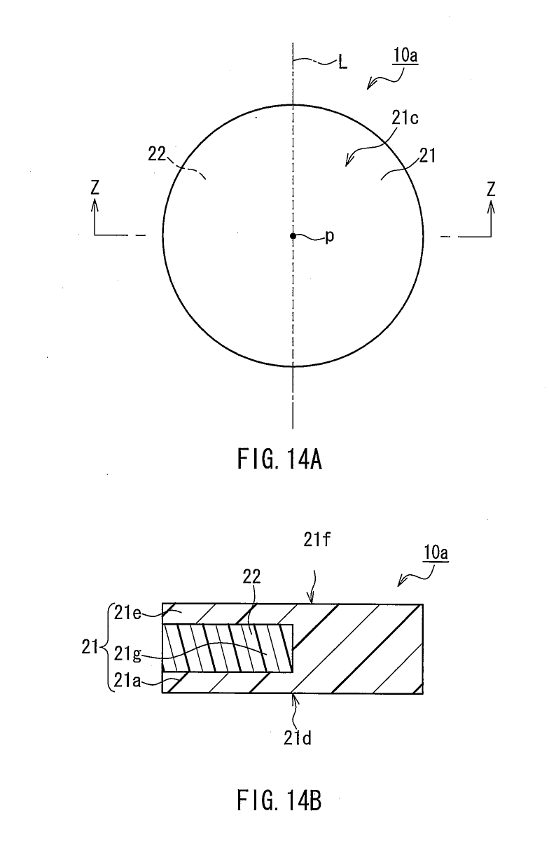

FIG. 14A is a plan view illustrating the configuration of Variation 4 of the foot section. FIG. 14B is a cross-sectional view of the Z-Z portion of FIG. 14A. In the foot section 10a illustrated in FIG. 14A and FIG. 14B, parts identical to those of the foot section 10a illustrated in FIG. 12A and the FIG. 12B are assigned identical reference numerals and their detailed descriptions are omitted.

In addition to the foot section 10a illustrated in FIG. 12A and FIG. 12B, the first supporting section 21 illustrated in FIG. 14A and FIG. 14B is further provided with an apparatus supporting section 21e.

The apparatus supporting section 21e is formed into a disk-like shape. The apparatus supporting section 21e is formed integrally with the shank section 21b from the same material as the resting contact section 21a and shank section 21b. The apparatus supporting section 21e faces the resting contact section 21a, with the second supporting section 22 sandwiched therebetween. The apparatus supporting section 21e has an upper surface 21f, which is formed in a planar shape. The upper surface 21f of the apparatus supporting section 21e is joined to the lower surface lb of the first enclosure 1.

The shank section 21g is formed into a half-cylinder shape. The shank section 21g is formed integrally with the resting contact section 21a and apparatus supporting section 21e.

The second supporting section 22 is formed into a half-cylinder shape. The material of the second supporting section 22 is the same as that of the second supporting section 22 illustrated in FIG. 7A and FIG. 7B. As shown in FIG. 14A, the interface between the first supporting section 21 and second supporting section 22 is located such that it passes through the center P of the foot section 10a.

Adopting such a configuration can ensure adhesion to the lower surface 1b of the first enclosure 1. Namely, since the apparatus supporting section 21e is provided with the upper surface 21f formed as a planar surface, when the foot section 10a is joined to the lower surface 1b of the first enclosure 1, it reliably can abut it in a planar fashion, and, therefore, the upper surface 21f can be reliably bonded to the lower surface 1b of the first enclosure 1.

In addition, in the configuration illustrated in FIG. 14A and FIG. 14B both the resting contact section 21a and apparatus supporting section 21e are formed into a disk-like shape, as a result of which assembly characteristics can be improved without identifying the orientation of the foot section 10a when the foot section 10a is joined to the lower surface 1b of the first enclosure 1. Namely, since the functionality does not change if the upper surface 21f or lower surface 21d of the foot section 10a is joined to the lower surface 1b of the first enclosure 1, the foot section 10a can be joined to the lower surface 1b of the first enclosure 1 without identifying the orientation of the foot section 10a. However, due to the fact that in the foot section 10a illustrated in FIG. 10A the second supporting section 22 is provided only on one side, with the line segment L passing through the center P illustrated in FIG. 10A used as a boundary, the position in the circumferential direction has to be identified when joining it to the lower surface 1b of the first enclosure 1.

It should be noted that in the above-described variations, as shown in FIG. 12 to FIG. 14, the central angles about the center P of the first supporting section 21 of the second supporting section 22 were described as equal angles. However, the central angles can be adjusted appropriate depending on the tendency of the first enclosure 1 to be tilted by batteries, HDDs, and other heavy items housed in the first enclosure 1 provided with the upper surface 21c of the first supporting section 21.

In this embodiment and in all the variations, the foot section 10a is an exemplary supporting member supporting the apparatus. The first supporting section 21 is an exemplary resting contact member. The resting contact section 21a is an exemplary resting contact section. The shank section 21b is an exemplary shank section. The apparatus supporting section 21e is an exemplary apparatus supporting section. The laptop computer is an exemplary electronic apparatus. The first enclosure 1 is an exemplary apparatus enclosure.

The disclosure of this Application is useful in electronic apparatus that can be set on a tabletop and the like. In addition, the disclosure of this Application is useful as a supporting member provided in an electronic apparatus.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A supporting member that is disposed in a foot installation section formed in an exterior surface of an apparatus enclosure and that supports an apparatus on a placement surface,
wherein the supporting member:
has a resting contact surface abutting the placement surface and an apparatus supporting surface abutting the foot installation section,
comprises a resting contact member whose one end face constitutes the resting contact surface, and a resilient member disposed closer to the apparatus supporting surface than to the resting contact surface of the resting contact member, and
can be deformed such that at least one of the gap between the resting contact surface and the apparatus supporting surface and the angle between the resting contact surface and the apparatus supporting surface changes when the apparatus is placed on the placement surface.

2. The supporting member according to claim 1, wherein the resilient member is disposed between the resting contact member and the foot installation section and is joined to the foot installation section such that the resting contact member is separated from the foot installation section.

3. The supporting member according to claim 2, wherein a concave section is formed in the center of the resting contact surface of the resting contact member and the resting contact member is threadedly connected to the enclosure by a screw disposed so as to pass through the thickness of the resilient member and a bore section formed in the center of the concave section.

4. The supporting member according to claim 1, wherein the resting contact member is formed from a shank section whose one end is joined to the foot installation section and a resting contact section having a larger outside diameter than the shank diameter of the shank section, the resilient member being at least partially disposed around the shank section.

5. The supporting member according to claim 4,
wherein the resting contact member further comprises an apparatus supporting section that has an outside diameter larger than the shank diameter of the shank section and that is integral with the one end of the shank section.

6. The supporting member according to claim 5, wherein the resting contact section and the apparatus supporting section of the resting contact member have identical geometry

7. An electronic apparatus,
wherein a plurality of foot installation sections are formed in the exterior surface of the apparatus enclosure that faces the placement surface, and
at least one foot section among a plurality foot sections disposed in the respective foot installation sections is the supporting member according to claim 1.

8. The electronic apparatus according to claim 7, wherein the foot installation sections are located in concave sections formed in the exterior surface of the apparatus enclosure, and the resting contact surfaces of the foot sections disposed in the foot installation sections protrude beyond the exterior surface of the apparatus enclosure.
